(19) United States
(12) Patent Application Publication
(10) Pub. No.: US 2026/0334336 A1
(43) Pub. Date: Oct. 22, 2026

(54) SEMICONDUCTOR PACKAGE ASSEMBLY AND A METHOD FOR FORMING THE SAME

(71) Applicant: STATS ChipPAC Management Pte. Ltd., Singapore (SG)

(72) Inventors: JongTae KIM, Incheon (KR); HangChul CHOI, Gyeonggi-do (KR); NamJu CHO, Gyeonggi-do (KR)

(21) Appl. No.: 19/650,385

(22) Filed: Apr. 17, 2026

(30) Foreign Application Priority Data
Apr. 17, 2025 (CN) 202510481796.5

(51) Int. Cl. H10W 90/00; H10W 40/20; H10W 70/00; H10W 72/00; H10W 76/01; H10W 76/15; H10W 90/22

(52) U.S. Cl. CPC H10W 90/401; H10W 40/242; H10W 70/099; H10W 72/823; H10W 76/01; H10W 76/15; H10W 90/22; H10W 90/736

(57) ABSTRACT

A semiconductor package assembly includes a base substrate; a lower electronic component mounted on the base substrate; a lower lid mounted on the base substrate, wherein the lower lid has a top plate thermally coupled to the lower electronic component to dissipate heat generated by the lower electronic component, and at least one opening passing through the top plate and exposing partially the base substrate; at least one interconnection structure vertically aligned with the at least one opening and mounted on the base substrate through the at least one opening; an interposer mounted on the at least one interconnection structure and electrically coupled to the base substrate via the at least one interconnection structure; one or more upper electronic components mounted on the interposer and electrically coupled to the base substrate via the interposer and the at least one interconnection structure; and an upper lid mounted on the lower lid and the one or more upper electronic components.

### TECHNICAL FIELD

The present application generally relates to semiconductor technology, and more particularly, to a semiconductor package assembly and a method for forming a semiconductor package assembly.

### BACKGROUND OF THE INVENTION

The semiconductor industry is constantly faced with complex integration challenges as consumers want their electronics to be smaller, faster and higher performance with more and more functionalities packed into a single device. In order to meet the needs of the consumers, more and more electronic components are integrated within a single package, which leads to bigger semiconductor packages. However, bigger semiconductor packages may have various drawbacks such as package warpage, unsatisfactory heat dissipation performance, etc.

Therefore, a need exists for a semiconductor package assembly with a compact structure.

### SUMMARY OF THE INVENTION

An objective of the present application is to provide a semiconductor package assembly with a compact structure.

According to an aspect of the present application, a semiconductor package assembly is provided. The semiconductor package assembly comprises: a base substrate; a lower electronic component mounted on the base substrate; a lower lid mounted on the base substrate and enclosing the lower electronic component, wherein the lower lid has a top plate thermally coupled to the lower electronic component to dissipate heat generated by the lower electronic component, and at least one opening passing through the top plate and exposing partially the base substrate; at least one interconnection structure vertically aligned with the at least one opening and mounted on the base substrate through the at least one opening; an interposer mounted on the at least one interconnection structure and electrically coupled to the base substrate via the at least one interconnection structure; one or more upper electronic components mounted on the interposer and electrically coupled to the base substrate via the interposer and the at least one interconnection structure; and an upper lid mounted on the lower lid and the one or more upper electronic components and enclosing the one or more upper electronic components and the interposer.

According to another aspect of the present application, a method for forming a semiconductor package assembly is disclosed. The method comprises: providing a base substrate; mounting a lower electronic component on the base substrate; mounting at least one interconnection structure on the base substrate; mounting a lower lid having a top plate with at least one openings passing therethrough on the base substrate to enclose the lower electronic component and the at least one interconnection structure and thermally couple a top plate of the lower lid to the lower electronic component, wherein the at least one opening exposes partially the base substrate and is aligned vertically with the at least one interconnection structure; mounting an interposer on the at least one interconnection structure to electrically couple the interposer to the base substrate via the at least one interconnection structure; mounting one or more upper electronic components on the interposer to electrically couple the one or more upper electronic components to the base substrate via the interposer and the at least one interconnection structure; and mounting an upper lid on the lower lid and the one or more upper electronic components to enclose the one or more upper electronic components and the interposer.

According to another aspect of the present application, a method for forming a semiconductor package assembly is disclosed. The method comprises: providing a base substrate; mounting a lower electronic component on the base substrate; mounting at least one interconnection structure on the base substrate; mounting a lower lid having a top plate with at least one openings passing therethrough on the base substrate to enclose the lower electronic component and the at least one interconnection structure and thermally couple a top plate of the lower lid to the lower electronic component, wherein the at least one opening exposes partially the base substrate and is aligned vertically with the at least one interconnection structure; mounting an interposer with one or more upper electronic components mounted thereon on the at least one interconnection structure to electrically couple the one or more upper electronic components on the interposer to the base substrate via the interposer and the at least one interconnection structure; and mounting an upper lid on the lower lid and the one or more upper electronic components to enclose the one or more upper electronic components and the interposer.

It is to be understood that both the foregoing general description and the following detailed description are exemplary and explanatory only, and are not restrictive of the invention. Further, the accompanying drawings, which are incorporated in and constitute a part of this specification, illustrate embodiments of the invention and together with the description, serve to explain principles of the invention.

### BRIEF DESCRIPTION OF DRAWINGS

The drawings referenced herein form a part of the specification. Features shown in the drawing illustrate only some embodiments of the application, and not of all embodiments of the application, unless the detailed description explicitly indicates otherwise, and readers of the specification should not make implications to the contrary.

FIG. 1A shows a semiconductor package assembly according to an embodiment of the present application.

FIG. 1B shows a top view of a lower lid of the semiconductor package assembly shown in FIG. 1A.

FIG. 2 shows a semiconductor package assembly according to another embodiment of the present application.

FIGS. 3A to 3G show a method for forming a semiconductor package assembly according to an embodiment of the present application.

FIG. 4 shows a method for forming an interconnection structure according to an embodiment of the present application.

FIG. 5 shows a method for forming an interposer according to an embodiment of the present application.

The same reference numbers will be used throughout the drawings to refer to the same or like parts.

### DETAILED DESCRIPTION OF THE INVENTION

The following detailed description of exemplary embodiments of the application refers to the accompanying drawings that form a part of the description. The drawings illustrate specific exemplary embodiments in which the application may be practiced. The detailed description, including the drawings, describes these embodiments in sufficient detail to enable those skilled in the art to practice the application. Those skilled in the art may further utilize other embodiments of the application, and make logical, mechanical, and other changes without departing from the spirit or scope of the application. Readers of the following detailed description should, therefore, not interpret the description in a limiting sense, and only the appended claims define the scope of the embodiment of the application.

In this application, the use of the singular includes the plural unless specifically stated otherwise. In this application, the use of “or” means “and/or” unless stated otherwise. Furthermore, the use of the term “including” as well as other forms such as “includes” and “included” is not limiting. In addition, terms such as “element” or “component” encompass both elements and components including one unit, and elements and components that include more than one subunit, unless specifically stated otherwise. Additionally, the section headings used herein are for organizational purposes only, and are not to be construed as limiting the subject matter described.

As used herein, spatially relative terms, such as “beneath”, “below”, “above”, “over”, “on”, “upper”, “lower”, “left”, “right”, “vertical”, “horizontal”, “side” and the like, may be used herein for ease of description to describe one element or feature’s relationship to another element(s) or feature(s) as illustrated in the figures. The spatially relative terms are intended to encompass different orientations of the device in use or operation in addition to the orientation depicted in the figures. The device may be otherwise oriented (rotated 90 degrees or at other orientations) and the spatially relative descriptors used herein may likewise be interpreted accordingly. It should be understood that when an element is referred to as being “connected to” or “coupled to” another element, it may be directly connected to or coupled to the other element, or intervening elements may be present.

The present invention relates to semiconductor package assemblies having a compact structure, to address various drawbacks for bigger semiconductor packages. In some embodiments, a semiconductor package assembly may have an embedded heat spreader lid which is capable of dissipating heat to an external environment of the semiconductor package assembly, and thus the semiconductor package assembly may have improved heat dissipation performance. Furthermore, the embedded heat spreader lid can also provide support for the other components within the semiconductor package assembly, which may be stacked on the embedded heat spreader. As such, the semiconductor package assembly can be compact in structure, and have a low risk of package warpage. Therefore, the reliability of the semiconductor package assembly can be improved.

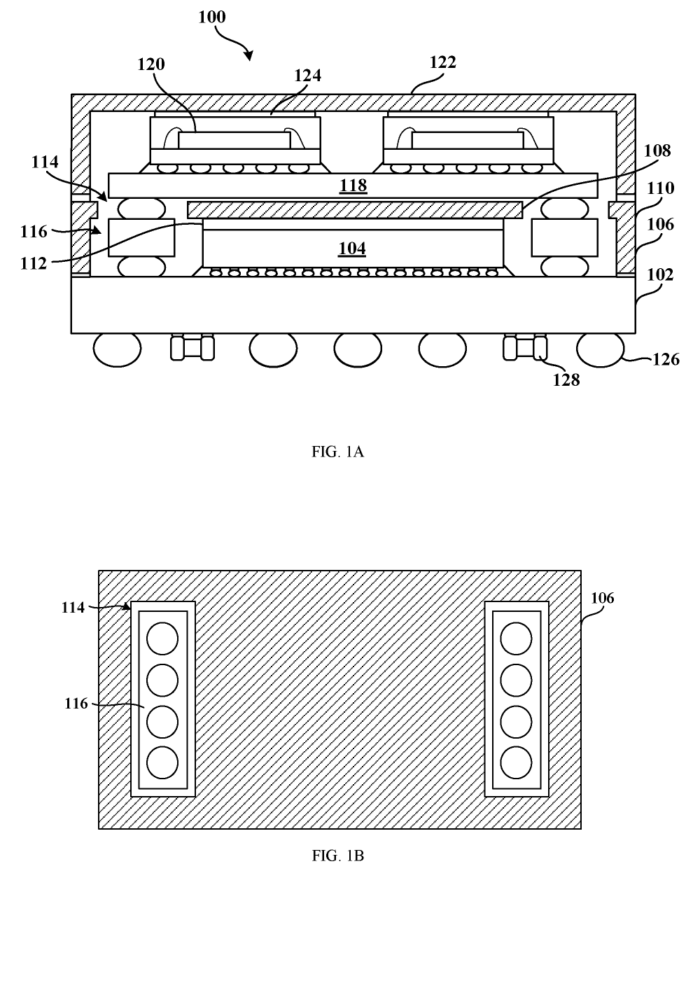

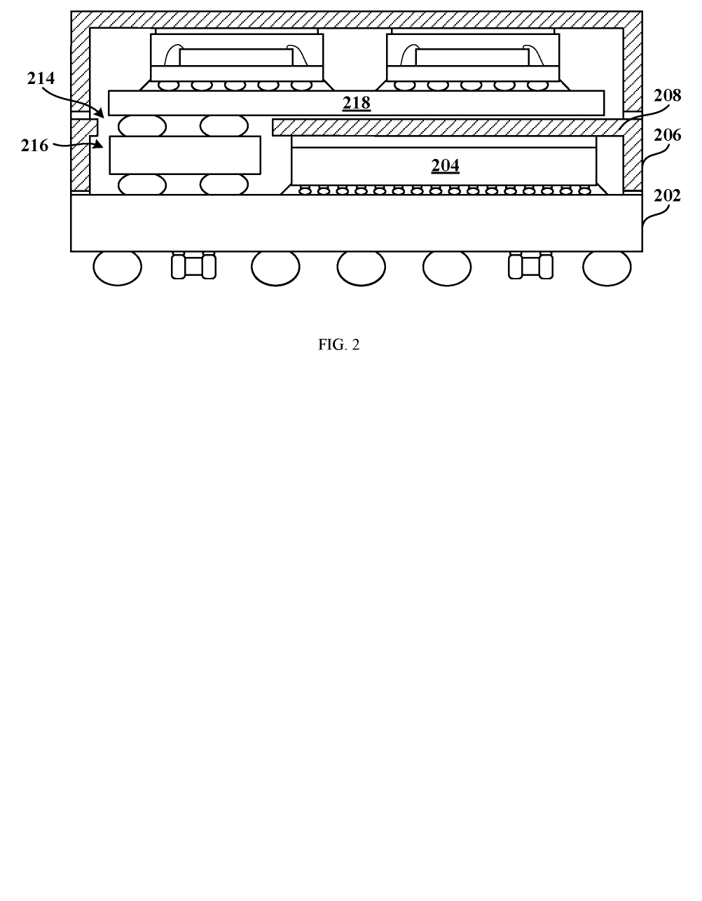

FIG. 1A shows a semiconductor package assembly 100 according to an embodiment of the present application.

As shown in FIG. 1A, the semiconductor package assembly 100 includes a base substrate 102 where various components and other structures are mounted and formed. The base substrate 102 includes a front side facing upward in the direction shown in FIG. 1A, and a back side opposite to the front side. In some embodiments, the base substrate 102 may be made of silicon or other semiconductor materials, or may include a printed circuit board (PCB), a carrier substrate, a ceramic substrate, a laminate interposer, a strip interposer, a leadframe, or other suitable substrates. In some examples, the base substrate 102 may include redistribution layers or structures having one or more dielectric layers and one or more conductive layers between and through dielectric layers. Thus, the various components and other structure on either one side or both sides of the base substrate 102 may be electrically coupled with each other to form an integrated electronic system. In the embodiment shown in FIG. 1A, most of the electronic components are mounted on the front side of the base substrate 102, only solder bumps 126 and some passive discrete electronic components 128 such as resistors are mounted on the back side of the base substrate 102. As such, the electronic components mounted on the front side of the base substrate 102 can be electrically coupled to the solder bumps 126 through the base substrate 102, and be further electrically coupled to an external system such as a power system or a controller when the semiconductor package assembly 100 is connected with such external system.

A lower electronic component 104 is mounted on the front side of the base substrate 102, for example, via solder bumps or other similar conductive structures. In some embodiments, the lower electronic component 104 may be a semiconductor chip or a semiconductor package. In the embodiment shown in FIG. 1A, the lower electronic component 104 has a relatively big size and can occupy a significant portion of a front surface of the base substrate 102. For example, the lower electronic component 104 may be a signal processing chip or a controller chip, which may generate a lot of heat during operation, and thus it is desired to dissipate the heat generated by the lower electronic component 104 to the external environment to avoid heat accumulation there. In some alternative embodiments, more than one lower electronic components 104 may be mounted on the front side of the base substrate 102, a portion or all of which may need specific heat dissipation paths or means.

A lower lid 106 is further mounted on a front side of the base substrate 102. The lower lid 106 can have a bigger size (in length, width and height) than the lower electronic component 104, such that it can enclose the lower electronic component 104 for protection and other purposes. In other words, the lower lid 106 and the base substrate 102 define together a lower chamber where the lower electronic component 104 is accommodated. As shown in FIG. 1A, the lower lid 106 has a top plate 108 which has an area that is substantially equal to that of the base substrate 102. Furthermore, a sidewall 110 of the lower lid 106 is connected to the top plate 108 and extends downward from the top plate 108. The sidewall 110 is attached to the base substrate 102 via an adhesive material, such that the top plate 108 can be firmly supported on and fixed to the base substate 102. It can be appreciated that in some other embodiments, the lower lid 106 can be attached or connected to the base substrate 102 in other appropriate manners, e.g., using fasteners. The sidewall 110 of the lower lid 106 can have a height slightly greater than that of the lower electronic component 104 when it is mounted on the base substrate 102. In that case, a gap may exist between the top plate 108 and a top surface of the lower electronic component 104, to avoid conflict therebetween during the mounting of the lower lid 106 onto the base substrate 102. As aforementioned, the lower electronic component 104 may generate significant heat during operation, while the lower lid 106 can be made of metal such as copper or alumina, or any other suitable materials with a good thermal conductivity. As such, the lower electronic component 104 can be thermally coupled to the lower lid 106, e.g., at the top plate 108, to dissipate heat generated by the lower electronic component 104 out to the external environment. For example, a thermal interface material layer 112 may be formed in the gap between the top plate 108 and the lower electronic component 104 to achieve the desired thermal coupling. It can be appreciated that in some embodiments where two or more lower electronic components 104 are mounted on the base substrate 102, each of the lower electronic components 104 can be thermally coupled to the lower lid 106 via, for example, a thermal interface material layer 112, or a portion of the lower electronic components 104 which may generate significant heat can be thermally coupled to the lower lid 106.

The lower lid 106 further has at least one opening 114 passing through the top plate 108. FIG. 1B shows a top view of the lower lid 106 of the semiconductor package assembly 100 shown in FIG. 1A. As shown in FIGS. 1A and 1B, two openings 114 are formed in the lower lid 106 which are generally opposite to each other with relative to a center of the top plate 108. However, it can be appreciated that other number of openings can be formed depending on the needs. The openings 114 do not break in entirety the connection from the central portion of the top plate 108 to the sidewall 110 of the lower lid 106, and thus heat generated by the lower electronic component 104 can still be effectively transferred across the openings 114 from the central portion to the edge of the top plate 108 and then to the sidewall 110 where it can be dissipated to the external environment.

In addition, the openings 114 of the lower lid 106 are vertically offset from the lower electronic component 104, and thus they can expose partially the base substrate 102, and in particular, some conductive pads formed on the base substrate 102 which are not covered by the lower electronic component 104. Accordingly, at least one interconnection structure 116 can be vertically aligned with the at least one opening 114 respectively, and be mounted on the base substrate 102 through the at least one opening 114. In the embodiment shown in FIGS. 1A and 1B, two openings 114 are formed in the lower lid 106, and each of the interconnection structures 116 is mounted within one of the openings 114. The interconnection structure 116 may include an e-bar block with solder bumps mounted or formed on both sides. The e-bar block is a type of integrated interconnection structure which can be pre-formed with various internal conductive pillars such as copper pillars extending through an insulating material such as a molding material. Depending on the number of conductive pillars, a corresponding number of solder bumps may be formed between the e-bar block and the base substrate 102 to enable electrical connection therebetween. Furthermore, a corresponding number of solder bumps may be similarly formed between the e-bar block and another component or structure above the e-bar block, which will be elaborated below in more details. Each interconnection structure 116 (with the height of the solder bumps on the front side of the interconnection structure 116 taken into account) may have a height equal to or slightly greater than that of the lower lid 106, such that another component or structure can be mounted on the base substrate 102 indirectly through the interconnection structure 116, to avoid interference with the lower lid 106. In some alternatively embodiments, the interconnection structure 116 may be a set of bigger solder balls with a height slightly greater than that of the lower lid 106. For example, each of the bigger solder balls may include a copper core with a tin coating, which can provide not only electrical conductivity but also desired thermal conductivity. In the embodiment shown in FIG. 1B, each of the openings 114 is shaped as a rectangle, and thus more than one solder balls may be mounted or attached with the interconnection structure 116 in a column. In some other embodiments where two or more columns of solder balls may be mounted or attached with the interconnection structure 116 depending on the actual needs.

The lower lid 106 provides for a direct heat dissipation path from the lower electronic component 104 to the external environment, while not restricting electrical connectivity to the base substrate 102. Thus, additional components can be stacked on the base substrate 102 and above the lower lid 116. In particular, an interposer 118 is further mounted on the at least one interconnection structure 116 and electrically coupled to the base substrate 102 via the at least one interconnection structure 116. For example, the interposer 118 may have backside conductive pads (not shown) which are aligned and connected with the solder bumps on the front side of the interconnection structures 116. Furthermore, the interconnection structures 116 can also support and fix the interposer 118 on the base substrate 102. As aforementioned, since the interconnection structures 116 (including the solder balls on their respective front sides) are generally taller than the lower lid 106, the interposer 118 can be supported on the base substrate 102 without interfering with the lower lid 106.

One or more upper electronic components 120 such as semiconductor chips or semiconductor packages or other appropriate electronic components can be mounted on the interposer 118. Due to the existence of the interconnection structures 116 and the interposer 118, the upper electronic components 120 can be electrically coupled to the base substrate 102 and operate with the lower electronic component 104 as a single integrated electronic system. Furthermore, an upper lid 122 can be further mounted on the lower lid 106, e.g., via an adhesive material. The upper lid 122 encloses the upper electronic components 120 and the interposer 118 and can thus protect them from the external environment and damages. In other words, the upper lid 122 and the lower lid 106 define together an upper chamber for accommodating the upper electronic components 120, which is generally separated from the lower chamber defined by the lower lid 106 and the base substrate 102. For example, the upper lid 122 can be made of alumina, copper or other similar metal or alloy materials. Preferably, the upper lid 122 may have a footprint the same as that of the lower lid 106. Since the upper lid 122 is supported on the lower lid 106, or particularly, on the top plate 108 of the lower lid 106, it may not block the heat dissipation path from the sidewall 110 of the lower lid 106 to the external environment. In some embodiments, the lower lid 106 may be made of alumina, copper or other similar metal or alloy materials, which can operate as an electromagnetic interference shielding layer, and thus, electromagnetic interferences between the electronic components within the two chambers can be reduced or avoided.

In some embodiments, the upper electronic components 120 may include packages with memory chips integrated therein, while the lower electronic component 104 may be a logic chip which may generate a significant amount of heat during operation and desire an efficient heat dissipation path. The lower lid 106 with a part embedded within the entire semiconductor package assembly 100 and another part exposed to the external environment can provide the desired direct heat dissipation path for the lower electronic component 104. Furthermore, as the upper electronic components 120 and the upper lid 122 is stacked over the lower lid 106, the entire semiconductor package assembly 100 can be compact in structure, which can reduce the risk of package warpage. Furthermore, it can be appreciated that in some alternative embodiments, the lower electronic component 104 and the upper electronic components 120 may be semiconductor devices with any other appropriate types of functionalities. For example, in some embodiments where more memory resource is needed, the lower electronic component 104 can be a memory chip or package, while the upper electronic components 120 can be semiconductor packages with logic circuits or functionalities.

In the embodiment shown in FIG. 1A, two smaller semiconductor packages are mounted on the interposer 118, which may have substantially the same height. Other than being supported on the lower lid 106, the upper lid 122 can also be mounted on the two upper electronic components 120, for example, via an adhesive material 124 between them. In this way, the upper lid 122 provides additional anchor for the upper electronic components 120 and thus structural reliability of the entire semiconductor package assembly 100 can be improved. In some embodiments, the adhesive material 124 between the upper electronic components 120 and the upper lid 122 may also be thermal conductive, which can provide a direct heat dissipation path for the upper electronic components 120.

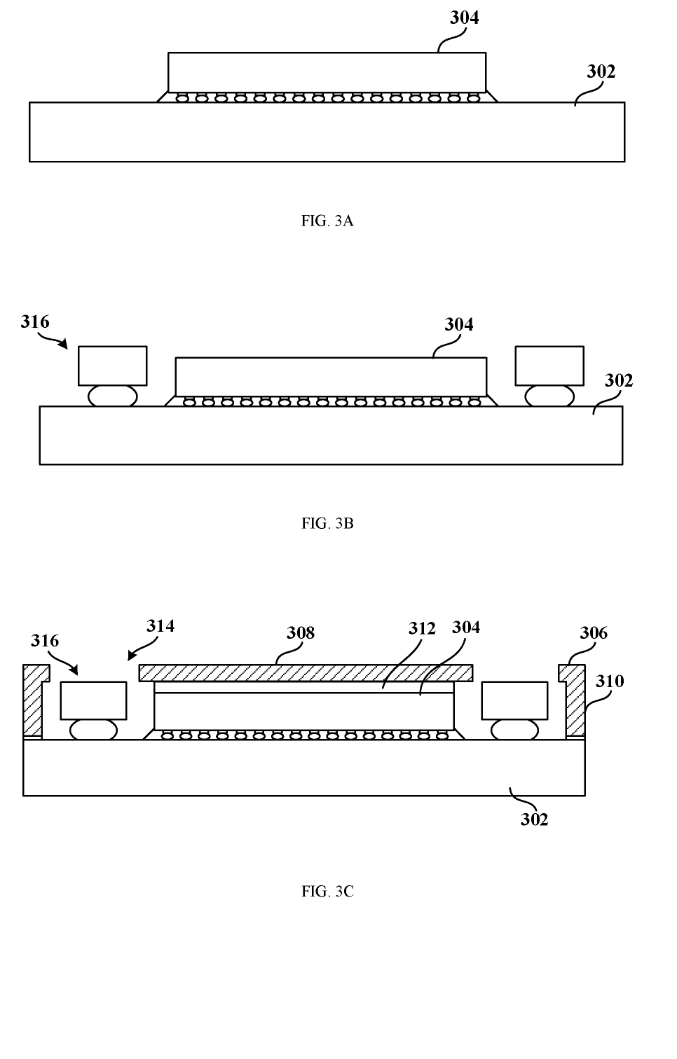

FIG. 2 shows a semiconductor package assembly 200 according to an embodiment of the present application. As shown in FIG. 2, different from the semiconductor package assembly 100 shown in FIG. 1A, which has the lower electronic component 104 mounted under the central region of the lower lid 106 and the at least one interconnection structure 116 distributed around the lower electronic component 104 and closer to the sidewall 110 of the lower lid 106, the semiconductor package assembly 200 has a lower electronic component 204 which is vertically offset from a central region of a lower lid 206. Accordingly, an interconnection structure 216 of the semiconductor package assembly 200 is also vertically offset from the central region of the lower lid 206, which is used to electrically and mechanically connect an interposer 218 with a base substrate 202. In other words, in the embodiment shown in FIG. 2, the two or more interconnection structures are formed as a single piece which may facilitate its attachment onto the base substrate 202. Accordingly, an opening 214 is formed through a top plate 208 of the lower lid 206 to allow the interconnection structure 216 to pass through the lower lid 206. As the opening 214 may occupy only a portion of an area of the top plate 208, a heat dissipation path can still be established from the lower electronic component 204 to an external environment through the lower lid 204. It can be appreciated the position and number of openings in the top plate of the lower lid can be modified according to the layout of the components mounted on the base substrate.

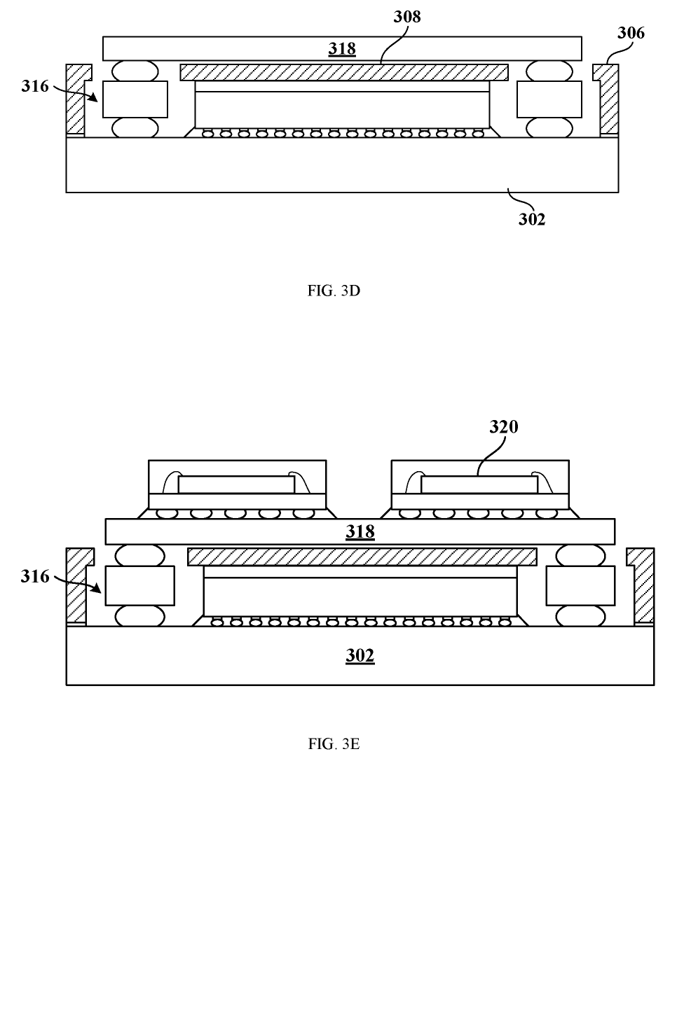

FIGS. 3A to 3G show a method for forming a semiconductor package assembly according to an embodiment of the present application. For example, the method can be used to form the semiconductor package assembly 100 shown in FIG. 1A, or the semiconductor package assembly 200 shown in FIG. 2 with certain modifications.

As shown in FIG. 3A, a base substrate 302 is provided. In some embodiments, the base substrate 302 may be made of silicon or other semiconductor materials, or may include a printed circuit board (PCB), a carrier substrate, a ceramic substrate, a laminate interposer, a strip interposer, a leadframe, or other suitable substrates. A lower electronic component 304 such as a semiconductor chip is mounted on the base substrate 302, for example, via solder bumps. An underfill material may be filled between the lower electronic component 304 and the base substrate 302 to improve the attachment of the lower electronic component 304 to the base substrate 302. In the embodiment, the lower electronic component 304 is mounted at a central region of the base substrate 302, but in some alternative embodiments, the lower electronic component 304 can be offset from the central region.

Next, as shown in FIG. 3B, two interconnection structures 316 are mounted on the base substrate 302, at two opposite sides of the lower electronic component 304 and close to an edge of the base substrate 302. In the embodiment, each of the two interconnection structures 316 includes an e-bar block with a set of solder bumps on its back side, which allow the interconnection structure 316 to be mounted on the base substrate 302. The two interconnection structures 316 may take an elongated plate form which has a backside surface sufficient for mounting of one or more columns of solder bumps. It can be appreciated that other number of interconnection structures 316 can be mounted on the base substrate 302.

In the embodiment, the e-bar block and the underneath solder bumps of each interconnection structure 316 can be pre-formed as a single piece, and then the interconnection structure 316 can be disposed onto the base substrate 302 together at a predetermined position. A reflowing process may be implemented to reflow the solder bumps and fix the interconnection structures 316 with the base substrate 302. As the interconnection structures may serve as anchors for components which will be subsequently mounted, they may have a desired height to avoid any potential interferences. Furthermore, in some other embodiments, the interconnection structures 316 can be mounted on the base substrate 302 prior to the mounting of the lower electronic component 304, rather than after the mounting of the lower electronic component 304.

Next, as shown in FIG. 3C, a lower lid 306 is mounted on the base substrate 302, for example, via an adhesive material dispensed on the back side of the lower lid 306. For example, the adhesive material can be dispensed between a sidewall 310 of the lower lid 306 and the base substrate 302. After the lower lid 306 is mounted, the lower electronic component 304 and the interconnection structures 316 can be enclosed by the lower lid 306. In particular, the lower lid 306 has a top plate 308 on its front side, and at least one opening 314 passing through the top plate 308. In the embodiment shown in FIG. 3C where two interconnection structures 316 are mounted on the base substrate 302, two openings 314 may be formed through the top plate 308, each of which is aligned with one of the interconnection structures 316. As the lower electronic component 304 is vertically offset from the openings 314, the openings 314 can expose partially the base substrate 302, or particularly, expose the interconnection structures 316 mounted on the base substrate 302.

In some embodiments, a thermal interface material layer 312 may be formed between the lower electronic component 304 and the top plate 308 of the lower lid 306, such that the lower lid 306 and the lower electronic component 304 can be thermally coupled with each other, to provide a heat dissipation path from the lower electronic component 304 to the external environment through the lower lid 306. For example, the thermal interface material layer 312 may be dispensed or otherwise formed on the top surface of the lower electronic component 304 before the lower lid 306 is mounted onto the base substrate 302. In that case, the thermal interface material layer 312 below the top plate 308 and the adhesive material below the sidewall 310 both enhance the attachment of the lower lid 306 to the base substrate 302, thereby improving the reliability of the semiconductor package assembly.

Next, as shown in FIG. 3D, an interposer 318 is mounted on the at least one interconnection structure 316 to electrically couple the interposer 318 to the base substrate 302 via the at least one interconnection structure 316. In the embodiment, solder bumps may be pre-formed with the interposer 318 on its back side, which can be aligned with respective conductive pads or other conductive patterns on the front side of the e-bar blocks of the interconnection structures 316 when the interposer 318 is being mounted on the at least one interconnection structure 316. As the solder bumps below the interposer 318 have certain height and elevate the interposer 318 relative to the base substrate 302, the top surface of the e-bar blocks of the interconnection structures 316 may be slightly recessed relative to the lower lid 306. However, a total height of each of the interconnection structures 316 including the e-bar block and the solder bumps on its both sides should be equal to or greater than a height of the lower lid 306, to avoid interferences therebetween.

Next, as shown in FIG. 3E, one or more upper electronic components 320 can be mounted on the interposer 318 to electrically couple the one or more upper electronic components 320 to the base substrate 302 via the interposer 318 and the at least one interconnection structure 316. In some embodiments, the upper electronic components 320 may be semiconductor packages, which can be mounted onto the interposer 318 via solder bumps or other similar bonding means. In some preferred embodiments, the upper electronic components 320 can have the same height or similar heights.

Next, as shown in FIG. 3F, an upper lid 322 is mounted on the lower lid 306 and the one or more upper electronic components 320 to enclose the one or more upper electronic components 320 and the interposer 318. For example, an adhesive material may be dispensed between the top plate 308 of the lower lid 306 and the upper lid 322 to connect them with each other. Preferably, the adhesive material may also be dispensed on the top surfaces of the upper electronic components 320, which can fill the respective gaps between the upper electronic components 320 and the upper lid 322 and enhance the attachment of the upper lid 322 to the other parts of the semiconductor package assembly. In some optional embodiments, a molding material may be filled within the upper lid 322 after the upper lid 322 is mounted on the lower lid 306 and the one or more upper electronic components 320. For example, one or more openings (not shown) may be formed through the upper lid 322 to enable filling of the molding material. The openings may be blocked by the molding material afterwards and thus may not adversely affect air impermeability of the entire semiconductor package assembly.

Next, as shown in FIG. 3G, the entire semiconductor package assembly may be flipped over, and then solder bumps 326 and additional electronic components 328 such as certain passive discrete electronic components may be mounted on the back side of the base substrate 302, which can be electrically coupled to the electronic components such as the lower electronic components 316 and the upper electronic components 320 on the front side of the base substrate 302. As such, the semiconductor package assembly can be formed.

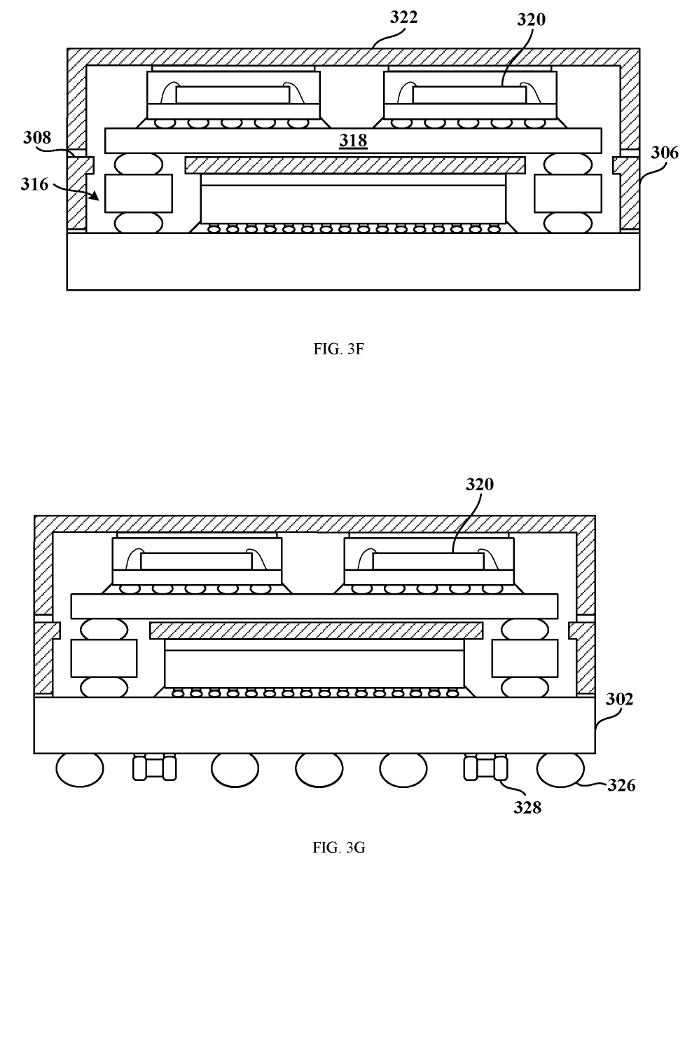

FIG. 4 shows a method for forming an interconnection structure according to an embodiment of the present application. The interconnection structure may be the interconnection structure 316 shown in FIG. 3C. As shown in FIG. 4, the interconnection structure may be singulated from a substrate strip 432 having multiple identical or similar interconnection units 416. In particular, all the interconnection units 416 of the substrate strip 432 may be processed together in a batch, for example, be mounted with respective sets of backside solder bumps. Afterwards, the substrate strip 432 may be singulated into pieces with each interconnection unit being one of the pieces. The batch processing can not only improve efficiency but also reduce difficulty in manufacturing, especially in cases where the individual interconnection structures have a relatively small size, e.g., smaller than one centimeter. It can be appreciated that the interconnection structures may not be mounted with their respective frontside solder bumps, which may be mounted with the interposers, as elaborated below.

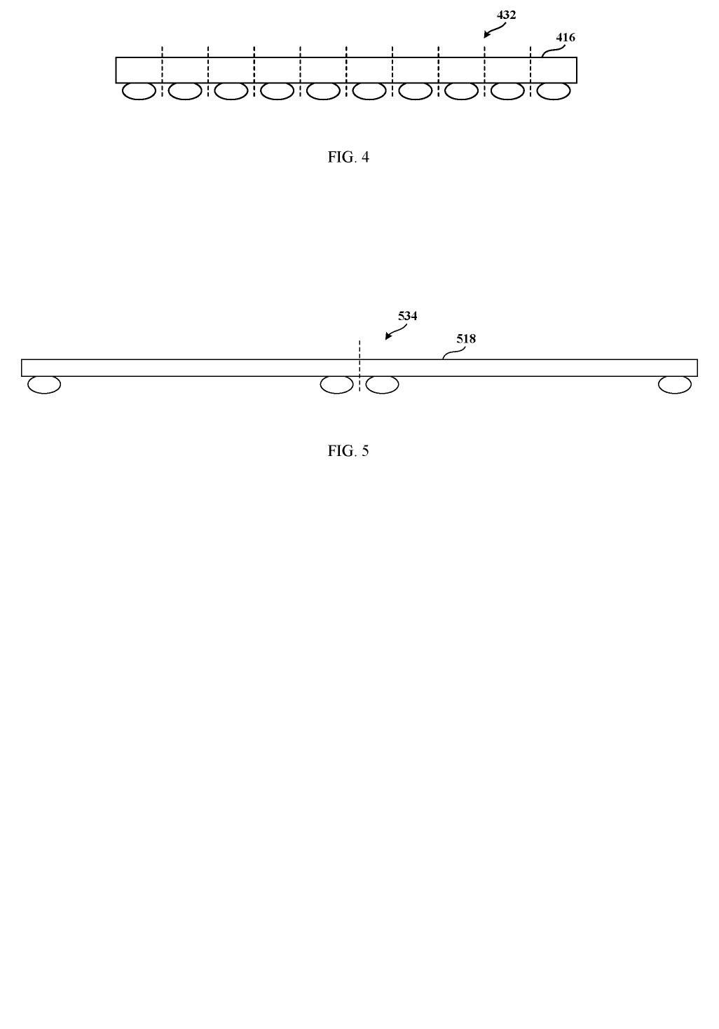

FIG. 5 shows a method for forming an interposer according to an embodiment of the present application. The interposer may be the interposer 318 shown in FIG. 3D. As shown in FIG. 5, the interposer may be singulated from an interposer strip 534 having multiple identical or similar interposer units 518. In particular, all the interposer units 518 of the interposer strip 534 may be processed together in a batch, for example, be mounted with respective sets of solder bumps on its back side. Afterwards, the interposer strip 534 may be singulated into pieces with each interposer unit being one of the pieces.

In some alternative embodiments, besides that the sets of solder bumps are mounted in advance on the interposer strip, respective sets of upper electronic components can be also mounted in advance on a back side of the interposer strip before the interposer strip is singulated into pieces. In that case, after singulation, an interposer with solder bumps on its back side and upper electronic components on its front side can be together mounted on the interconnection structures shown in FIG. 3C, i.e., the mounting steps shown in FIGS. 3D and 3E can be performed in a single step, which improves the efficiency of the entire packaging process.

The discussion herein included numerous illustrative figures that showed various portions of a semiconductor package assembly and a method for forming the semiconductor package assembly. For illustrative clarity, such figures did not show all aspects of each example assembly. Any of the example assemblies and/or methods provided herein may share any or all characteristics with any or all other assemblies and/or methods provided herein.

Various embodiments have been described herein with reference to the accompanying drawings. It will, however, be evident that various modifications and changes may be made thereto, and additional embodiments may be implemented, without departing from the broader scope of the invention as set forth in the claims that follow. Further, other embodiments will be apparent to those skilled in the art from consideration of the specification and practice of one or more embodiments of the invention disclosed herein. It is intended, therefore, that this application and the examples herein be considered as exemplary only, with a true scope and spirit of the invention being indicated by the following listing of exemplary claims.

1. A semiconductor package assembly, comprising:
a base substrate;
a lower electronic component mounted on the base substrate;
a lower lid mounted on the base substrate and enclosing the lower electronic component, wherein the lower lid has a top plate thermally coupled to the lower electronic component to dissipate heat generated by the lower electronic component, and at least one opening passing through the top plate and exposing partially the base substrate;
at least one interconnection structure vertically aligned with the at least one opening and mounted on the base substrate through the at least one opening;
an interposer mounted on the at least one interconnection structure and electrically coupled to the base substrate via the at least one interconnection structure;
one or more upper electronic components mounted on the interposer and electrically coupled to the base substrate via the interposer and the at least one interconnection structure; and
an upper lid mounted on the lower lid and the one or more upper electronic components and enclosing the one or more upper electronic components and the interposer.

2. The semiconductor package assembly of claim 1, wherein each of the at least one interconnection structure comprises an e-bar block with solder bumps mounted on its both sides.

3. The semiconductor package assembly of claim 1, wherein each of the at least one interconnection structure comprises a solder ball with a copper core.

4. The semiconductor package assembly of claim 1, wherein the lower electronic component is under a central region of the lower lid, and the at least one interconnection structure is distributed around the lower electronic component and closer to a sidewall of the lower lid.

5. The semiconductor package assembly of claim 1, wherein the lower electronic component is vertically offset from a central region of the lower lid, and the at least one interconnection structure is also vertically offset from the central region of the lower lid.

6. The semiconductor package assembly of claim 1, wherein the top plate of the lower lid is attached to the lower electronic component via a thermal interface layer.

7. The semiconductor package assembly of claim 1, wherein the lower electronic component is a semiconductor chip.

8. The semiconductor package assembly of claim 1, wherein the lower electronic component, the lower lid, the one or more upper electronic components and the upper lid are all mounted at a front side of the base substrate, and the semiconductor package further comprises solder bumps mounted at a back side of the base substrate.

9. The semiconductor package assembly of claim 8, wherein the semiconductor package further comprises at least one backside electronic components mounted on the back side of the base substrate.

10. A method for forming a semiconductor package assembly, comprising:
providing a base substrate;
mounting a lower electronic component on the base substrate;
mounting at least one interconnection structure on the base substrate;
mounting a lower lid having a top plate with at least one openings passing therethrough on the base substrate to enclose the lower electronic component and the at least one interconnection structure and thermally couple a top plate of the lower lid to the lower electronic component, wherein the at least one opening exposes partially the base substrate and is aligned vertically with the at least one interconnection structure;
mounting an interposer on the at least one interconnection structure to electrically couple the interposer to the base substrate via the at least one interconnection structure;
mounting one or more upper electronic components on the interposer to electrically couple the one or more upper electronic components to the base substrate via the interposer and the at least one interconnection structure; and
mounting an upper lid on the lower lid and the one or more upper electronic components to enclose the one or more upper electronic components and the interposer.

11. The method of claim 10, wherein each of the at least one interconnection structure comprises an e-bar block, and wherein mounting at least one interconnection structure on the base substrate further comprises:
mounting solder bumps on a back side of the e-bar block of each of the at least one interconnection structure;
attaching the e-bar blocks on the base substrate via the respective solder bumps; and
reflowing the solder bumps.

12. The method of claim 10, wherein mounting an interposer on the at least one interconnection structure further comprises:
mounting solder bumps on a back side of the interposer; and
attaching the interposer on the at least one interconnection structure via the solder bumps.

13. The method of claim 10, wherein before mounting a lower lid having a top plate with at least one openings passing therethrough on the base substrate, the method further comprises:
forming a thermal interface layer on the lower electronic component.

14. The method of claim 10, wherein the lower electronic component is a semiconductor chip.

15. The method of claim 10, wherein the lower electronic component, the lower lid, the one or more upper electronic components and the upper lid are all mounted at a front side of the base substrate, and the method further comprises:
mounting solder bumps on a back side of the base substrate.

16. A method for forming a semiconductor package assembly, comprising:
providing a base substrate;
mounting a lower electronic component on the base substrate;
mounting at least one interconnection structure on the base substrate;
mounting a lower lid having a top plate with at least one openings passing therethrough on the base substrate to enclose the lower electronic component and the at least one interconnection structure and thermally couple a top plate of the lower lid to the lower electronic component, wherein the at least one opening exposes partially the base substrate and is aligned vertically with the at least one interconnection structure;
mounting an interposer with one or more upper electronic components mounted thereon on the at least one interconnection structure to electrically couple the one or more upper electronic components on the interposer to the base substrate via the interposer and the at least one interconnection structure; and
mounting an upper lid on the lower lid and the one or more upper electronic components to enclose the one or more upper electronic components and the interposer.

17. The method of claim 16, wherein mounting an interposer with one or more upper electronic components mounted thereon on the at least one interconnection structure further comprises:
mounting solder bumps on a back side of the interposer;
mounting the one or more upper electronic components on a front side of the interposer; and
attaching the interposer on the at least one interconnection structure via the solder bumps.
